(19) United States
(12) Patent Application Publication
(10) Pub. No.: US 2015/0171370 A1
(43) Pub. Date: Jun. 18, 2015

(54) ORGANIC LIGHT-EMITTING DIODE DEVICE COMPRISING A SUBSTRATE INCLUDING A TRANSPARENT LAYERED ELEMENT

(71) Applicant: SAINT-GOBAIN GLASS FRANCE, Courbevoie (FR)

(72) Inventors: Marie-Virginie Ehrensperger, Paris (FR); Fabien Lienhart, Paris (FR); Michele Schiavoni, Paris (FR); Etienne Sandre-Chardonnal, Paris (FR)

(21) Appl. No.: 14/403,406

(22) PCT Filed: May 23, 2013
(86) PCT No.: PCT/FR2013/051123

§ 371 Date: Nov. 24, 2014

(30) Foreign Application Priority Data
May 25, 2012 (FR) 1254868

(51) Int. Cl. H01L 51/52; H01L 51/56; H01L 51/00

(52) U.S. Cl. CPC H01L 51/5262; H01L 51/5234; H01L 51/5206; H01L 51/5275; H01L 51/004; H01L 51/56

(57) ABSTRACT

An organic light-emitting diode device includes a carrier including a transparent layered element exhibiting specular transmission and diffuse reflection, the element being used as an extraction solution. A process for manufacturing the device and the use of the carrier in an organic light-emitting diode device are presented. Lastly, there is provided a carrier coated with an electrode suitable in particular for preparing the diode devices.

The present invention relates to an organic light-emitting diode device comprising a particular carrier and its manufacturing process. The invention also relates to a carrier coated with an electrode suitable in particular for preparing said diode devices. Lastly, the invention relates to the use of the carrier in an organic light-emitting diode device.

Organic light-emitting diodes (OLEDs) comprise an organic material, or stack of organic materials, that emits/emit light, and are flanked by two electrodes. One of the electrodes, called the lower electrode, generally the anode, is associated with a carrier such as a glazing substrate, and the other electrode, called the upper electrode, generally the cathode, is arranged on the organic material(s) opposite the anode.

OLEDs are devices that emit light by electroluminescence using the energy released when holes injected from the anode and electrons injected from the cathode recombine.

There are various OLED configurations:
bottom emitting devices, i.e. devices with a (semi) transparent lower electrode and a reflective upper electrode;
top emitting devices, i.e. devices with a (semi) transparent upper electrode and a reflective lower electrode; and
top-and-bottom emitting devices, i.e. devices with both a (semi) transparent lower electrode and a (semi) transparent upper electrode, which will possibly be referred to as transparent OLED devices below.

The invention more particularly relates to bottom emitting and top-and-bottom emitting OLED devices.

Conventionally, an OLED device comprises a carrier by way of a front substrate or glazing function substrate (glazing substrate below) and an optional encapsulation system. The carrier provides mechanical protection, while ensuring good transmission of the light. Conventionally, the encapsulation systems consist of a hollow glass cover adhesively bonded to the carrier. The cavity between the carrier and the cover is generally filled with an inert gas such as nitrogen and may contain a desiccant in order to minimize the amount of moisture in the vicinity of the organic layers.

In the case of the use of an OLED in an emissive device that emits only from one side, the cathode is in general not transparent, and the emitted photons pass through the transparent anode and the carrier of the OLED in order to deliver light from the device.

In the case of the use of an OLED in an emissive device that emits from two sides, the cathode and the anode are transparent, and the emitted photons pass through the transparent anode and/or cathode in order to deliver light from the device.

Organic light-emitting diode devices (OLED devices below) are new efficient, low-power sources of light. However, these devices have the drawback of having a luminous efficacy that is especially limited by confinement of light in the structure of the diode. This confinement of light is, on the one hand, due to a certain number of photons remaining trapped in guided modes between the cathode and anode, and, on the other hand, to reflection of the light within the glazing substrate as a result of the index difference between the glass of the substrate (n=1.5) and the air outside the device (n=1).

So-called “extraction” solutions have therefore been sought in order to increase the efficacy, and especially the gain in extraction, of OLEDs.

These extraction solutions are generally divided into two categories:
what are referred to as “layer-side” solutions, which consist in injecting as much light as possible into the carrier by minimizing the guiding effect of the transparent electrode and organic layers; and
what are referred to as “air-side” solutions, which consist an extracting the light reflected at the air/carrier interface.

Thus, in an ordinary system, without an extracting solution, only 20% of the light emitted by the diode is extracted from the structure. The use of extracting solutions turns out to be essential if a higher efficacy is to be achieved.

One known strategy for increasing the energy conversion efficiency of an OLED device consists in improving the transmission properties of the carrier forming the front substrate, by limiting reflection of incident light from this carrier.

Specifically, it is known to texture at least that external main surface of the carrier which is directed away from the OLED device with a plurality of raised geometric features that are concave or convex relative to a general plane of this face. These features may be micron- or millimeter-sized.

The features may especially be pyramids or cones, or even features, such as grooves or ribs, having a dominant longitudinal direction.

Carriers are also known comprising a substrate made of transparent glass coated with a scattering layer, such as described in patent application FR 2 937 467.

Solutions of this type, based either on the replacement of the smooth surface of the air/carrier interface with a textured surface, or on the introduction of a scattering effect into the substrate, allow an optical efficiency of about 70% to 80% to be obtained. Optical efficiency corresponds to the ratio between the light extracted from the device to the light available in the glass.

However, these prior-art solutions employing textured carriers or comprising scattering layers scatter light both in transmission and in reflection. Thus, these solutions have the drawback of modifying the final appearance of the OLED device, which then appears hazy in transmission. These extraction systems cannot therefore be used to manufacture transparent OLED devices as it is not possible to see clearly through the carrier. In addition, in bottom emitting devices comprising a reflective cathode producing a mirror effect, it may, especially for aesthetic reasons, be advantageous to preserve this mirror effect. However, the scattering properties in transmission of these extraction solutions prevents this mirror effect from being preserved.

Conventionally, reflection from a glazing pane is said to be diffuse when a light ray incident on the glazing pane with a given angle of incidence is reflected by the glazing pane in a plurality of directions. Reflection from a glazing pane is said to be specular when a light ray incident on the glazing pane with a given angle of incidence is reflected by the glazing pane with an angle of reflection equal to the angle of incidence. Analogously, transmission through a glazing pane is said to be specular when a light ray incident on the glazing pane with a given angle of incidence is transmitted by the glazing pane with an angle of transmission equal to the angle of incidence.

In addition, the air/carrier interface of prior-art solutions is not smooth, which is disadvantageous as it makes them difficult to clean and less attractive.

It is especially these drawbacks that the invention is more particularly intended to remedy by providing an OLED carrier comprising a particular layered element.

The solution provided according to the invention in any case allows extraction of the available light from the device to be improved via extraction of the light reflected at the air/carrier interface. In addition, in certain advantageous embodiments of the invention, the extraction solution also allows the amount of light injected into the carrier to be maximized by minimizing the guiding effect of the transparent electrode and organic layers.

For this purpose, one subject of the invention is an organic light-emitting diode device 6 comprising at least one organic light-emitting diode 7 and a carrier 5 comprising a transparent layered element 1 having two smooth main external surfaces 2A, 4A, characterized in that the layered element comprises:
two external layers 2, 4, which each form one of the two external main surfaces 2A, 4A of the layered element and which are composed of preferably dielectric, transparent materials having substantially the same refractive index n2, n4, and
a central layer 3 inserted between the external layers, this central layer 3 being formed either by a single layer which is a preferably dielectric, transparent layer with a refractive index n3 different from that of the external layers, or a metal layer, or by a stack of layers 3₁, 3₂, . . . , 3ₖ which comprises at least one preferably dielectric, transparent layer with a refractive index n3₁, n3₂, . . . , n3ₖ different from that of the external layers, or a metal layer,

in which each contact surface S₀, S₁, . . . , Sₖ between two adjacent layers of the layered element which are one transparent and of refractive index n2, n3, n4, n3₁, n3₂, . . . or n3ₖ and the other metal, or which are both transparent layers of different refractive indices, is textured and parallel to the other textured contact surfaces between two adjacent layers which are one transparent and of refractive index n2, n3, n4, n3₁, n3₂, . . . or n3ₖ and the other metal, or which are both transparent layers of different refractive indices.

In the context of the invention, a distinction is made between metal layers, on the one hand, for which the refractive index value is inconsequential, and, on the other hand, preferably dielectric, transparent layers having a preset refractive index, for which the refractive index difference relative to that of the external layers must be taken into account.

The particular carrier used according to the invention makes it possible to obtain specular transmission of an incident light ray originating from the diode onto the layered element and diffuse reflection of a light ray whatever the direction of the source through the carrier.

Surprisingly, the invention therefore allows:
light extraction from the OLED to be improved relative to a flat substrate, this improvement especially resulting in increased light extraction;
the final appearance of the diode to be improved by ensuring specular transmission of the light originating from the diode through the carrier, guaranteeing a clear view through the carrier comprising the layered element;
an extraction solution to be provided that preserves a smooth air/carrier interface surface having aesthetic advantages and making cleaning easier, especially in the case of a laminated configuration;
color properties at inclination to be improved and the intensity profile at inclination to be modified; and
in the particular case of transparent OLEDs emitting from two sides of the device, the light level emitted from each side of the diode to be adjusted.

The specular transmission of light originating from the diode or passing through the diode via the carrier makes the carrier of the invention usable as an extraction solution for transparent OLED devices. The same specular transmission property also allows a mirror-like appearance to be preserved in the case of diode devices comprising a reflective cathode equipped with the particular carrier of the invention.

The carrier therefore comprises an element that is transparent in transmission while exhibiting diffuse reflection. Throughout the description, the carrier according to the invention is regarded as being arranged horizontally, with its first face, directed downward, defining a lower external main surface and its second face, opposite the first face, directed upward, defining an upper external main surface; the meanings of the expressions “above” and “below” are thus to be considered with respect to this orientation. Unless otherwise specified, the expressions “above” and “below” do not necessarily mean that two elements, layers and/or coatings are placed in contact with each other. The terms “lower” and “upper” are used here with reference to this arrangement.

According to the invention, the one or more light-emitting diodes are placed above or below the carrier, i.e. either making contact with the second face of the carrier when the diodes are placed above, or making contact with the first face when the diodes are placed below.

The organic light-emitting diode comprises:
a preferably transparent first electrode formed from one or more layers,
above the first electrode, an organic light-emitting system, and
a second electrode formed from one or more layers, said electrode being deposited on the organic light-emitting system, opposite the first electrode.

To obtain a transparent organic light-emitting diode device, a transparent first and second electrode are used. To obtain an organic light-emitting diode device having a mirror effect, a transparent first electrode and a reflective second electrode are used.

The invention also relates to a carrier such as defined above coated with an electrode for an organic light-emitting diode device, characterized in that said carrier comprises at least one layered element. Preferably, the carrier comprises a first face and a second face opposite the first face and comprises above its second face or below its first face the electrode in the form of a layer.

Lastly, the invention relates to the use of a carrier in an organic light-emitting diode device, characterized in that said carrier comprises a transparent layered element 1.

The electrodes of the OLED preferably comprise at least one electrically conductive layer. Preferably, the electrode making contact with the carrier is an anode.

The electrically conductive layer may be composed of one of more materials chosen from ITO, ZnO:Al, SnO2:F, or a thin layer or a stack of thin layers containing a thin conductive layer of a metal such as Ag, Au or Cu.

The carrier may furthermore comprise at least one additional layer positioned above or below the layered element. Said additional layer or layers of the carrier may consist of preferably dielectric, transparent materials having very substantially the same refractive index or having refractive indices that are different from the preferably dielectric, transparent materials of the external layers of the layered element.

The carrier comprises two external main surfaces, an upper external main surface and a lower external main surface. The external main surfaces of the carrier are coincident with the external main surfaces of the layered element if the carrier does not comprise any additional layers. In contrast, if the carrier comprises:
at least one upper additional layer, the upper external main surface of the carrier will be coincident with the upper external main surface of the upper additional layer,
at least one lower additional layer, the lower external main surface of the carrier will be coincident with the lower external main surface of the lower additional layer.

In the context of the invention, the term “index” refers to the optical refractive index measured at a wavelength of 550 nm.

According to the invention, a thin layer is a layer that is smaller than 1 μm in thickness.

Two preferably dielectric, transparent materials or layers have substantially the same refractive index or have refractive indices that are substantially equal if the absolute value of the difference between their refractive indices at 550 nm is less than or equal to 0.15. Preferably, the absolute value of the refractive index difference at 550 nm between the preferably dielectric, transparent constituent materials of the two external layers of the layered element is smaller than 0.05 and better still smaller than 0.015.

Two preferably dielectric, transparent materials or layers have different refractive indices if the absolute value of the difference between their refractive indices at 550 nm is strictly larger than 0.15. According to one advantageous feature, the absolute value of the refractive index difference at 550 nm between, on the one hand, the external layers and, on the other hand, at least one transparent layer of refractive index (n3, n3₁, n3₂, . . . , n3ₖ) of the central layer is larger than or equal to 0.3, preferably larger than or equal to 0.5 and more preferably larger than or equal to 0.8.

Light rays originating from the diode that are initially in the extraction cone exit at the carrier/air interface. The relatively large refractive index difference at the at least one textured contact surface inside the layered element promotes reflection of light from this textured contact surface. Thus, light rays that would have been trapped by total internal reflection at the carrier/air interface may be reflected and scattered by the textured surface of the central layer and thus extracted from the device after a second reflection.

In the context of the invention, the following definitions are used.

The contact surface between two adjacent layers is the interface between two adjacent layers.

A transparent element is an element through which light rays are transmitted at least in the wavelength ranges used in the ultimate application of the element. By way of example, when the element is used in an architectural or automotive glazing unit, it will be transparent at least in the visible wavelength range.

According to the invention, the expressions “transparent materials” or “transparent layers” in particular refer to:
the external layers 2, 4 composed of transparent materials of refractive index n2, n4,
the central layer 3 formed by a transparent layer of refractive index n3,
the stack of layers 3₁, 3₂, . . . , 3ₖ that comprises at least one transparent layer with a refractive index n3₁, n3₂, . . . or n3ₖ different from that of the external layers.

Preferably, the transparent materials or layers are organic or mineral in nature. Preferably, the transparent materials or layers are not made of metal. Mineral transparent materials or layers may be chosen from oxides, nitrides or halides of one or more transition metals, nonmetals or alkaline-earth metals. The transition metals, nonmetals or alkaline-earth metals are preferably chosen from silicon, titanium, tin, zinc, indium, aluminum, molybdenum, niobium, zirconium or magnesium. Organic dielectric materials or layers are chosen from polymers.

These transparent materials or layers are preferably dielectrics. A dielectric material or layer is a material or layer that is/is made of a nonmetal. A material or layer with a low electrical conductivity, preferably lower than 10⁴ S/m and optionally lower than 100 S/m, is considered to be a dielectric material or layer. A material or layer having a resistivity higher than that of a metal may also be considered to be a dielectric material or layer. The dielectric materials or layers of the invention have a resistivity higher than 1 ohm centimeter (Ω.cm), preferably higher than 10 Ω.cm and optionally higher than 10⁴ Ω.cm.

According to one particular embodiment of the invention, the central layer and/or the upper external layer of the layered element may form one electrode of the OLED device, preferably the lower electrode. In this case, the central layer preferably comprises at least one metal layer. When the layers located above this layer are transparent layers of refractive index n2, n3₁, n3₂, . . . , n3ₖ, these layers must be conductive to a certain extent. The transparent materials or layers may therefore be electrically conductive layers. Specifically, these transparent materials or layers must have a resistivity that is “low” enough to ensure the electrode formed from this or these layers and the central layer of the layered element remains conductive. These layers or materials preferably have a resistivity lower than 1 ohm.cm and preferably lower than 10⁻² ohm.cm.

A rough or textured surface is a surface the surface properties of which vary on a scale that is larger than the wavelength of the light incident on the surface. The incident light is then transmitted and reflected diffusely by the surface. Preferably, a rough or textured surface according to the invention has a roughness parameter corresponding to the arithmetic average deviation Ra of at least 0.5 μm and especially comprised between 1 and 5 μm (corresponding to the arithmetic mean of all the absolute distances of the roughness profile R measured from a median line of the profile over an evaluation length).

A smooth surface is a surface the surface irregularities of which are such that light is not deviated thereby. Incident light rays are then transmitted and reflected specularly by the surface. Preferably, a smooth surface is a surface the surface irregularities of which have dimensions that are smaller or very much larger (large-scale undulations) than the wavelength of the light incident on the surface.

However, the external layers or the additional layers may contain certain surface irregularities provided that these layers make contact with one or more additional layers composed of dielectric materials having substantially the same refractive index and having, on the side thereof opposite that making contact with said layer containing certain irregularities, a smooth surface such as defined above.

Preferably, a smooth surface is a surface either having a roughness parameter corresponding to the arithmetic average deviation Ra lower than 0.1 μm and preferably lower than 0.01 μm, or slopes smaller than 10°.

A glazing pane corresponds to a mineral or organic transparent substrate.

The layered element may be rigid or flexible. It may in particular be a question of a glazing pane, made for example based on glass or a polymer material. It may also be a question of a flexible film based on a polymer material, especially one able to be added to a surface.

Specular transmission is obtained because the two external layers of the layered element have smooth external main surfaces and are composed of materials having substantially the same refractive index, and because each textured contact surface between two adjacent layers of the layered element which are one transparent and the other metal, or which are both transparent layers of different refractive indices, is parallel to the other textured contact surfaces between two adjacent layers which are one transparent and the other metal, or which are both transparent layers of different refractive indices.

The smooth external surfaces of the layered element ensure specular transmission of light rays at the air/external layer interface, i.e. ensure that light rays from the diode enter into the upper external layer and that light rays exit from the device via the lower external layer without changing direction. The parallelism of the textured contact surfaces implies that the or each constituent layer of the central layer, which is transparent and has a refractive index different from that of the external layers, or which is a metal, has a uniform thickness perpendicular to the contact surfaces between the central layer and the external layers.

This thickness may be uniform over the entire extent of the texture, or only locally over sections of the texture. In particular, when the texture comprises gradient variations, the thickness between two consecutive textured contact surfaces may change, in sections, depending on the slope of the texture, the textured contact surfaces however always remaining parallel to one another. This is especially the case for a layer deposited by cathode sputtering, the thickness of such a layer being inversely proportional to the slope of the texture. Thus, locally, in each section of texture having a given slope, the thickness of the layer remains constant, but the thickness of the layer differs between a first section of texture having a first slope and a second section of texture having a second slope different from the first slope.

Advantageously, in order to obtain the parallelism of the textured contact surfaces inside the layered element, the or each constituent layer of the central layer is a layer deposited by cathode sputtering.

Specifically, cathode sputtering, in particular magnetron cathode sputtering, guarantees that the surfaces bounding the layer are parallel to one another, which is not the case with other deposition techniques such as evaporation or chemical vapor deposition (CVD) or even the sol-gel process. The parallelism of the textured contact surfaces inside the layered element is however essential if specular transmission through the element is to be obtained.

A light ray incident on a first external layer of the layered element passes through this first external layer without changing direction. Because the first external layer and at least one layer of the central layer have different (metal or dielectric) natures or different refractive indices, the light ray is then refracted in the central layer. Because, on the one hand, the textured contact surfaces between two adjacent layers of the layered element which are one transparent and the other metal, or which are both transparent layers of different refractive indices, are all parallel to one another and, on the other hand, the second external layer has substantially the same refractive index as the first external layer, the angle of refraction of the light ray in the second external layer from the central layer is equal to the angle at which the light ray is incident on the central layer from the first external layer, in accordance with Snell's law of refraction.

The light ray therefore exits from the second external layer of the layered element in a direction that is the same as its direction of incidence onto the first external layer of the element. The transmission of the light ray by the layered element is thus specular. Thus, a clear view through the layered element is obtained, i.e. the layered element does not appear translucent, by virtue of the specular transmission properties of the layered element.

Advantageously, the device of the invention makes it possible to obtain a light transmission measured according to standard ISO 9050:2003 of at least 50%, preferably of at least 60% and better still of at least 75%, and a haze in transmission measured according to standard ASTM D 1003 lower than 20%, preferably lower than 10% and better still lower than 5%. These values are measured on the carrier side.

According to one aspect of the invention, at least one of the two external layers of the layered element composed of preferably dielectric, transparent materials is chosen from:
transparent substrates one of the main surfaces of which is textured and the other smooth, preferably chosen from polymers, glasses and ceramics,
a layer of transparent material chosen from oxides, nitrides or halides of one or more transition metals, nonmetals or alkaline-earth metals,
a layer based on curable materials initially in a liquid or pasty viscous state suitable for shaping operations comprising:
   photocrosslinkable and/or photopolymerizable materials,
   layers deposited by a sol-gel process,
   enamel layers,
interlayers or interleaves made of thermoformable or pressure-sensitive plastic which may preferably be based on polymers chosen from polyvinyl butyrals (PVB), polyvinyl chlorides (PVC), polyurethanes (PU), polyethylene terephthalates or ethylene/vinyl acetates (EVA).

The lower external layer is preferably a transparent substrate one of the main surfaces of which is textured and the other of which is smooth. One of the main surfaces of the transparent substrates may be textured using any known texturing process, for example by embossing the surface of the substrate, heated beforehand to a temperature at which it is possible to deform it, in particular by rolling by means of a roller having, at its surface, a texture complementary to the texture to be formed on the substrate; by abrasion by means of abrasive particles or surfaces, in particular by sandblasting; by chemical treatment, in particular treatment with acid in the case of a glass substrate; by molding, in particular injection molding, in the case of a substrate made of thermoplastic polymer; or by engraving.

When the transparent substrate is made of polymer, it may be rigid or flexible. Examples of polymers suitable according to the invention comprise in particular:
polyesters, such as polyethylene terephthalate (PET), polybutylene terephthalate (PBT) or polyethylene naphthalate (PEN);
polyacrylates, such as polymethyl methacrylate (PMMA);
polycarbonates;
polyurethanes;
polyamides;
polyimides;
fluoropolymers, such as the fluoroesters: ethylene-tetrafluoroethylene (ETFE), polyvinylidene fluoride (PVDF), polychlorotrifluoroethylene (PCTFE), ethylene-chlorotrifluoroethylene (ECTFE) or fluorinated ethylene-propylene copolymers (FEP);
photocrosslinkable and/or photopolymerizable resins, such as thiolene, polyurethane, urethane-acrylate or polyester-acrylate resins, and
polythiourethanes.

These polymers generally exhibit a refractive index range varying from 1.3 to 1.7. However, it is interesting to note that certain of these polymers, and especially sulfur-containing polymers such as the polythiourethanes, may have high refractive indices, possibly ranging up to 1.74.

Examples of glass substrates which may be used directly as the external layer of the layered element comprise:
glass substrates sold by Saint-Gobain Glass in the Satinovo® range, which are pretextured and exhibit, on one of their main surfaces, a texture obtained by sandblasting or acid attack;
glass substrates sold by Saint-Gobain Glass in the Albarino® S, P or G range or in the Masterglass® range, which exhibit, on one of their main surfaces, a texture obtained by rolling;
high index glass substrates which are textured by sandblasting, such as flint glass, for example sold by Schott under the references SF6 (n=1.81), 7SF57 (n=1.85), N-SF66 (n=1.92) and P-SF68 (n=2.00).

When each of the two external layers of the layered element is formed by a transparent substrate, the two transparent substrates have textures which complement one another.

The textured external layer of the layered element may be composed simply of a layer of dielectric material chosen from oxides, nitrides or halides of one or more transition metals, nonmetals or alkaline-earth metals. The transition metals, nonmetals or alkaline-earth metals are preferably chosen from silicon, titanium, tin, zinc, aluminum, molybdenum, niobium, zirconium or magnesium. This thin layer of dielectric material may be formed from materials chosen from high refractive index materials such as Si₃N₄, AlN, NbN, SnO₂, ZnO, SnZnO, Al₂O₃, MoO₃, NbO, TiO₂, ZrO₂ and InO and low refractive index materials such as SiO₂, MgF₂, AlF₃. This layer is preferably used as the upper external layer of the layered element and may be deposited using a cathode sputtering deposition technique, especially a magnetron cathode sputtering deposition technique, by evaporation or by chemical vapor deposition (CVD), on a carrier coated beforehand with a lower external layer and a central layer. On the other hand, the depositions produced by cathode sputtering conform to the surface. The layer thus deposited thus subsequently has to be polished, so as to obtain a flat main external surface. These dielectric layers thus comprise a textured surface matching the surface roughness of the central layer and an external main surface opposite this surface which is flat.

The external layers of the layered element may also be based on curable materials initially in a liquid or pasty viscous state suitable for shaping operations. Preferably, these layers are used as upper external layers of the layered element.

The layer initially deposited in a liquid or pasty viscous state may be a layer of photocrosslinkable and/or photopolymerizable material. Preferably, this photocrosslinkable and/or photopolymerizable material is provided in the liquid form at ambient temperature and gives, when it has been irradiated and photocrosslinked and/or photopolymerized, a transparent solid devoid of bubbles or any other irregularity. It may in particular be a resin, such as those normally used as adhesives or surface coatings. These resins are generally based on monomers/comonomers/prepolymers of epoxy, epoxysilane, acrylate, methacrylate, acrylic acid or methacrylic acid type. Mention may be made, for example, of thiolene, polyurethane, urethane-acrylate or polyester-acrylate resins. Instead of a resin, it may be a photocrosslinkable aqueous gel, such as a polyacrylamide gel. Examples of photocrosslinkable and/or photopolymerizable resins which may be used in the present invention comprise the products sold by Norland Optics under the NOA® Norland Optical Adhesives brand, such as, for example, the NOA®65 and NOA®75 products.

As a variant, the external layer initially deposited in a liquid or pasty viscous state may be a layer deposited by a sol-gel process, for example a silica glass deposited using a sol-gel process. As is known, the precursors for sol-gel deposition of a silica glass are silicon alkoxides Si(OR)₄ that, in the presence of water, undergo hydrolysis/condensation type polymerization reactions. These polymerization reactions result in the formation of increasingly condensed entities, which lead to colloidal silica particles forming sols and then gels. The drying and the densification of these silica gels, at a temperature of about a few hundred degrees, produces a glass, the characteristics of which are similar to those of a conventional glass. As a result of their viscosity, the colloidal solution or the gel may easily be deposited, on the textured main surface of the central layer opposite the first external layer, conformal to the texture of this surface.

This deposition may especially be carried out by dip coating, spin coating or blading. The layers deposited using the sol-gel process planarize the surface of the layered element. However, when use is made of such planarization layers, the external main surface of this so-called planarization layer may contain certain surface irregularities. In order to smooth the external layer of the carrier, it is possible to place, in contact with this surface containing certain irregularities, an additional layer, such as a plastic interlayer or sheet such as described below, having substantially the same refractive index as said external layer.

Another example of an external layer may be obtained by deposition of an enamel based on a glass frit on a glass substrate, for example a soda-lime glass substrate. In this case, the enamel per se is not scattering and does not comprise compounds or structures such as air bubbles liable to provide it with such properties. In order to obtain the enamel, a formulation comprising a glass frit is first of all prepared by grinding the glass to particle sizes of a few microns (for example D50=2 microns), this ground glass then being formed into a paste using an organic matrix. A layer of this composition is then deposited on the glass substrate by a liquid-route deposition technique, such as screen printing or slot coating. Finally, this layer is fired at a temperature higher by at least 100° C. with respect to the glass transition temperature of the glass frit used in the composition. The enamel layer corresponds to a layer based on curable materials initially in a liquid, viscous or pasty state suitable for shaping operations.

The enamel layer, when it is used as the lower external layer, may subsequently be rendered rough or textured by chemical attack in solutions having extreme pH values, that is to say either strongly acidic (pH<2) or strongly basic (pH>12). In this case, the glass substrate is considered to be an additional layer of the carrier and the enamel layer is considered to form the external layer of the layered element.

The enamel layer may also be used as the upper external layer. In this case, the textured upper external layer of the layered element may be composed simply of an enamel composition based on glass frit deposited by a liquid-route deposition technique (such as screen printing or slot coating) on a carrier precoated with a lower external layer and with a central layer. The enamel layer will “fill in” the roughness of the central layer. This layer comprises a surface matching the surface roughness of the central layer, which is thus textured, and an external main surface opposite this surface which is flat. However, in this case, with regard to the high firing temperatures required to melt the composition comprising the glass frit, it is necessary to make sure that the materials employed in the carrier, i.e. the materials of the external layer coated with the central layer, are not liable to deform as a result of this firing step. For example, if use is made of a carrier composed of a glass substrate comprising a textured enamel as the lower external layer, it is preferable for the enamel composition comprising the glass frit intended to form the upper external layer to exhibit a glass transition temperature Tg which is lower than the glass transition temperature of the frit composition used to form the enamel of the lower external layer. Thus, the lower external layer is not deformed during the step of firing the upper external layer.

This preparation process using glass enamel compositions allows external layers having low or high refractive indices to be produced for the layered element. For example, if a high index enamel composition is deposited a substrate coated with a high index textured external layer is obtained. To obtain high refractive index enamel layers it is sufficient to use an enamel composition comprising a glass frit rich in heavy elements, such as an enamel rich in bismuth, for example with a bismuth content higher than 40% by weight.

The external layer may comprise a layer based on an interlayer or sheet made of thermoformable or pressure-sensitive plastic, this layer being positioned against that textured main surface of the central layer which is opposite the first external layer and shaped against this textured surface by compression and/or heating. This layer based on polymer material may in particular be a layer based on polyvinyl butyral (PVB), on ethylene/vinyl acetate (EVA), on polyurethane (PU), on polyethylene terephthalate (PET) or on polyvinyl chloride (PVC). These layers may be shaped by compression and/or heating.

The thickness of the external layer is preferably comprised between 1 μm and 6 mm and varies depending on the choice of the preferably dielectric, transparent material.

The flat or textured glass substrates preferably have a thickness comprised between 0.4 and 6 mm and more preferably between 0.7 and 2 mm.

The flat or textured polymer substrates preferably have a thickness comprised between 0.020 and 2 mm and more preferably between 0.025 and 0.25 mm.

The external layers composed of a layer of preferably dielectric, transparent materials preferably have a thickness comprised between 0.2 and 20 μm and more preferably between 0.5 and 2 μm.

The layers based on curable materials initially in a liquid or pasty viscous state suitable for shaping operations preferably have a thickness comprised between 0.5 and 40 μm and more preferably between 0.5 and 7 μm. The layers based on photocrosslinkable and/or photopolymerizable materials preferably have a thickness comprised between 0.5 and 20 μm and more preferably between 0.7 and 10 μm. The layers deposited by a sol-gel process preferably have a thickness comprised between 1 and 40 μm and more preferably between 10 and 15 μm. The enamel layers based on glass frit preferably have a thickness comprised between 3 and 30 μm and more preferably between 5 and 20 μm.

The layers based on a plastic interlayer or sheet preferably have a thickness comprised between 10 μm and 1 mm and more preferably comprised between 0.3 and 1 mm. The preferably dielectric, transparent materials or layers may have:
a refractive index comprised between 1.51 and 1.53, for example in the case where a standard glass is used;
a refractive index lower than 1.51 and preferably lower than 1.49 in the case where a low refractive index material or layer is used, for example if a low refractive index enamel is used; or
a refractive index higher than 1.54 and preferably higher than 1.7 in the case where a high refractive index material or layer is used, for example if a high refractive index enamel is used.

In one particularly advantageous embodiment of the invention, the materials used to form the upper and lower layers of the layered element are high refractive index materials.

The resulting extraction solution makes it possible both to inject as much light as possible into the carrier by minimizing the guiding effect of the transparent electrode and organic layers and to extract the light reflected at the air/carrier interface. According to the invention, the expression “high refractive index material” is understood to mean a material having an index comprised between 1.7 and 2.4, preferably between 1.75 and 2.1 and even between 1.8 and 2.0. These high refractive index materials may especially be chosen from glasses, polymers such as sulfonated polymers, layers of dielectric materials and enamel layers.

The layer or stack of layers of the central layer of the layered element may comprise a layer chosen from:
at least one adhesive layer made of transparent polymer,
at least one thin layer composed of a preferably dielectric, transparent material chosen from oxides, nitrides or halides of one or more transition metals, nonmetals or alkaline-earth metals,
at least one thin metal layer, in particular a thin layer of silver, gold, copper, titanium, niobium, silicon, aluminum, nickel-chromium alloy (NiCr), stainless steel or their alloys.

The thin layer composed of a preferably dielectric, transparent material may be chosen from:
at least one thin layer composed of a preferably dielectric, transparent material having a high refractive index different from the refractive index of the external layers, such as Si₃N₄, AlN, NbN, SnO₂, ZnO, SnZnO, Al₂O₃, MoO₃, NbO, TiO₂, ZrO₂ or InO,
at least one thin layer composed of a preferably dielectric, transparent material having a low refractive index different from the refractive index of the external layers, such as SiO₂, MgF₂ or AlF₃.

When the central layer comprises an oxide, the latter may be doped. The central layer may, for example, be a layer of tin-doped indium oxide, aluminum-doped zinc oxide or fluorine-doped tin oxide.

When the central layer is an adhesive layer made of transparent polymer, the external layers are assembled together by means of this central layer formed by a layer of dielectric material with a different refractive index from that of the external layers.

The choice of the thickness of the central layer depends on a certain number of parameters. Generally, it is considered that the total thickness of the central layer is comprised between 5 and 200 nm, and the thickness of a layer of the central layer is comprised between 1 and 200 nm.

When the central layer is a metal layer, the thickness of a layer is preferably comprised between 5 and 40 nm, better still comprised between 6 and 30 nm and even better still from 6 to 20 nm.

When the central layer is a preferably dielectric, transparent layer, for example of TiO₂, it preferably has a thickness comprised between 20 and 100 nm and better still 55 and 65 nm and/or a refractive index comprised between 2.2 and 2.4.

When the OLED device is transparent, i.e. it comprises a transparent cathode and a transparent anode, it is possible to adjust the light level emitted from each side of the diode for example by choosing the thickness and nature of the central layer, especially its reflection coefficient. Specifically, it will be readily understood that in a transparent diode device the greater the reflectivity of the central layer, the more emission from the side opposite that of the carrier will be increased. In this case, use of the particular carrier of the invention not only makes it possible to promote extraction but also to adjust the light level on each side of the device. Another possible way of modifying the light level emitted from each side of the diode is to choose a central layer having a different reflection coefficient on each of its sides. For example, a central layer having a high reflection coefficient on the air/carrier interface side and a low reflection coefficient on the diode/carrier side will increase illumination on the air/carrier side.

Advantageously, the composition of the central layer of the layered element may be adjusted in order to confer additional properties on the layered element, for example thermal properties, of solar control and/or low emissivity type. Thus, in one embodiment, the central layer of the layered element is a transparent stack of thin layers comprising an alternation of “n” metal functional layers, in particular of functional layers' based on silver or silver-comprising metal alloy, and of “(n+1)” antireflection coatings, with n≧1, where each metal functional layer is positioned between two antireflection coatings.

In a known way, such a stack having a metal functional layer exhibits reflection properties in the range of solar radiation and/or in the range of long-wavelength infrared radiation. In such a stack, the metal functional layers essentially determine the thermal performance, while the antireflection coatings which frame them act interferentially on the optical aspect. This is because, while the metal functional layers make it possible to obtain the desired thermal performance even at a small geometrical thickness, of about 10 nm for each metal functional layer, they are, however, strongly opposed to the passage of light rays in the range of visible wavelengths. Consequently, antireflection coatings on either side of each metal functional layer are necessary to ensure good light transmission in the visible range.

These additional functionalities may be advantageous in architectural applications. Specifically, the device of the invention may be used in a glazing unit in which the carrier is placed on the external side and the diode on the internal side of the dwelling. In this case, the carrier of the invention, in addition to forming an OLED extraction solution, ensures that the OLED is protected from harmful radiation such as UV radiation. Furthermore, the system may provide a solar control function when the central layer is sufficiently conductive.

According to one aspect of the invention, the texture of each contact surface between two adjacent layers of the layered element which are one transparent (and preferably not made of a metal) while the other is a metal, or which are two transparent layers of different refractive indices, is formed by a plurality of features that are recessed or project with respect to a general plane of the contact surface. Preferably, the mean height of the features of each contact surface between two adjacent layers of the layered element which are one transparent and the other metal, or which are two transparent layers of different refractive indices, is comprised between 1 micrometer and 1 millimeter. Within the meaning of the invention, the mean height of the features of the contact surface is defined as the arithmetic mean of the distances yᵣ in absolute value, taken between the peak and the general plane of the contact surface for each feature of the contact surface, equal to

$$\frac{1}{n} {\sum }_{i = 1}^{n} \vert {y}_{i} \vert .$$

The features of the texture of each contact surface between two adjacent layers of the layered element which are one transparent and the other metal, or which are two transparent layers of different refractive indices, may be distributed randomly over the contact surface. As a variant, the features of the texture of each contact surface between two adjacent layers of the layered element which are one transparent and the other metal, or which are two transparent layers of different refractive indices, may be distributed periodically over the contact surface. These features may in particular be cones, pyramids, grooves, ribs or wavelets.

According to one aspect of the invention, for each layer of the central layer which is flanked by layers having a transparent (preferably nonmetal) or metal nature different from its own or having refractive indices different from its own, the thickness of this layer, taken perpendicularly to its contact surfaces with the adjacent layers, is small with respect to the mean height of the features of each of its contact surfaces with the adjacent layers. Such a small thickness makes it possible to increase the probability that the entry interface of a light ray into this layer and the departure interface of the light ray out of this layer are parallel and thus to increase the percentage of specular transmission of light through the layered element. Advantageously, the thickness of each layer of the central layer which is inserted between two layers having a transparent (preferably nonmetal) or metal nature different from its own or having refractive indices different from its own, where this thickness is taken perpendicularly to its contact surfaces with the adjacent layers, is less than ¼ of the mean height of the features of each of its contact surfaces with the adjacent layers.

The central layer is formed either by a single layer deposited conformally on the textured main surface of the first external layer or by a stack of layers successively deposited conformally on the textured main surface of the first external layer.

According to the invention, it is considered that the central layer is deposited conformally on the textured main surface of the first external layer if, subsequent to the deposition, the upper surface of the central layer is textured and parallel to the textured contact surface of the first external layer. The deposition of the central layer conformally or of the layers of the central layer conformally in succession on the textured main surface of the first external layer is preferably carried out by cathode sputtering, in particular magnetron cathode sputtering.

The additional layers are preferably chosen from:
transparent substrates chosen from polymers, glasses or ceramics as defined above but comprising two smooth main surfaces,
curable materials initially in a liquid or pasty viscous state suitable for shaping operations as described above,
interlayers or sheets made of thermoformable or pressure-sensitive plastic as described above.

Advantageously, the smooth external main surfaces of the layered element and/or the smooth external main surfaces of the carrier are flat or curved; preferably, these smooth external main surfaces are parallel to one another. This contributes to limiting the light dispersion of light crossing the layered element and thus to improving the sharpness of the view through the layered element.

The carrier may be a rigid glazing pane or a flexible film. Such a flexible film is advantageously provided, on one of its external main surfaces, with an adhesive layer covered with a protective strip intended to be removed for the adhesive bonding of the film. The carrier comprising this layered element taking the form of a flexible film is then able to be added by adhesive bonding to an existing surface, to an OLED for example, and thus to form the device of the invention.

In one embodiment of the invention, a first external layer among the two external layers of the layered element, preferably the lower external layer, is a transparent substrate. The central layer is formed either by a single layer deposited conformally on the textured main surface of the first external layer or by a stack of layers successively deposited conformally on the textured main surface of the first external layer. Preferably, the central layer is deposited by cathode sputtering, in particular magnetron cathode sputtering. The second external layer or upper external layer preferably comprises a layer of curable material that is initially in a liquid or pasty viscous state, or an interlayer of thermoformable or pressure-sensitive material deposited on the textured main surface of the central layer opposite the first external layer.

According to another aspect of the invention, when the upper external layer comprises a layer of curable material that is initially in a liquid or pasty viscous state, an additional layer may be used as a counter-substrate. The layer that is initially deposited in a liquid or pasty viscous state then ensures a secure bond between the lower external layer provided with the central layer and the counter-substrate.

According to another aspect of the invention, when the upper external layer comprises a layer based on an interlayer or sheet made of a thermoformable or pressure-sensitive plastic, an additional layer, for example a transparent substrate of refractive index substantially equal to those of the external layers, may be used. The layer based on a plastic interlayer or sheet then corresponds to a lamination interlayer ensuring the bond between the lower external layer of the layered element coated with the central layer and the additional layer.

The carrier of the organic light-emitting diode device of the invention preferably comprises the following stack:
optionally at least one lower additional layer chosen from transparent substrates, the two main surfaces of which are smooth, such as polymers and glasses and interlayers made of thermoformable or pressure-sensitive plastic;
a lower external layer chosen from transparent substrates, such as polymers and glasses and curable materials initially in a liquid or pasty viscous state suitable for shaping operations, such as enamel layers;
a central layer comprising a thin layer composed of a preferably dielectric, transparent material of refractive index (n3), or a thin metal layer;
an upper external layer chosen from transparent substrates chosen from polymers and glasses, curable materials initially in a liquid or pasty viscous state suitable for shaping operations and interlayers made of thermoformable or pressure-sensitive plastic; and
optionally at least one upper additional layer chosen from transparent substrates, the two main surfaces of which are smooth, chosen from polymers and glasses and interlayers made of thermoformable or pressure-sensitive plastic.

In one variant of the invention, the carrier of the organic light-emitting diode device comprises:
a lower external layer chosen from transparent substrates made of rough glass;
a central layer preferably comprising a thin TiO₂ layer;
an upper external layer chosen from photocrosslinkable and/or photopolymerizable resins; and
an upper additional layer chosen from transparent substrates made of flat glass.

According to another embodiment, the carrier of the organic light-emitting diode device of the invention preferably comprises the following stack:
a lower external layer for the layered element, said layer being chosen from transparent substrates made of rough glass;
a central layer preferably comprising a thin TiO₂ layer;
an upper external layer chosen from interlayers made of thermoformable or pressure-sensitive plastic, preferably a layer based on polyvinyl butyral; and
an upper additional layer chosen from transparent substrates made of flat glass.

According to another embodiment, the carrier of the organic light-emitting diode device of the invention comprises the following stack:
a lower external layer chosen from transparent substrates made of rough glass;
a central layer preferably comprising a thin TiO₂ layer;
an upper external layer chosen from a layer obtained by a sol-gel process; and
optionally, an upper additional layer chosen from interlayers made of thermoformable or pressure-sensitive material, on which another upper additional layer chosen from transparent glass substrates is preferably superposed.

In the particularly advantageous embodiment of the invention referred to as the “high refractive index” embodiment, the upper and lower external layers of the layered element are composed of preferably dielectric, transparent materials having a high refractive index comprised between 1.7 and 2.4, preferably between 1.75 and 2.1 and better still between 1.8 and 2.

According to this embodiment, the carrier preferably comprises the following stack:
a lower external layer chosen from transparent substrates made of glass or high index polymer; or
a lower additional layer chosen from transparent substrates made of glass coated with an external layer consisting of a high refractive index enamel layer, for example an enamel layer obtained from an enamel composition having a bismuth content higher than 40% by weight; and
a central layer comprising a thin layer composed of a preferably dielectric, transparent material, preferably SiO₂ or TiO₂, or a thin metal layer, preferably a layer composed of Ag, NiCr, Ti, Cu or Au; and
an upper external layer chosen from a transparent substrate made of polymer or of high index glass, a high index enamel layer or a layer of preferably dielectric, high index transparent material.

In one advantageous embodiment of the invention, the central layer of the layered element and/or the upper external layer of the layered element may form the lower electrode (or first electrode) of the organic light-emitting diode. According to this embodiment, but not only in this embodiment, the central layer is preferably a metal layer or optionally comprises a metal layer in order to provide the central layer with the electrode function. In addition, the upper external layer of the layered element is preferably composed of transparent materials, preferably nonmetals, having a resistivity lower than 1 ohm.cm, preferably lower than 10⁻¹ ohm.cm and better still lower than 10⁻² ohm.cm. Lastly, in this embodiment the layered element preferably comprises external upper and lower layers composed of transparent materials with a high refractive index.

According to this embodiment, the carrier of the organic light-emitting diode device of the invention preferably comprises the following stack:
a lower external layer chosen from glass substrates and polymer substrates; or
a lower additional layer chosen from transparent substrates made of glass coated with an external layer composed of a high refractive index enamel composition; and
a central layer, preferably a metal layer such as a thin layer composed of Ag; and
an upper external layer comprising a layer of transparent material.

The lower external layer preferably comprises a substrate made of glass or polymer having a high refractive index.

The upper external layer preferably comprises a layer of transparent material chosen from Si₃N₄, AlN, NbN, SnO₂, ZnO, SnZnO, Al₂O₃, MoO₃, NbO, TiO₂ and ZrO₂, and more particularly SnZnO, Si₃N₄ or ZnO, having a resistivity lower than 1 ohm.cm and preferably having a thickness comprised between 0.5 et 20 μm.

In another embodiment of the invention, the materials used to form the upper and lower layers of the layered element are low refractive index materials. The carrier of the organic light-emitting diode device of the invention may comprise a layered element comprising the following stack:
a lower external layer composed of materials chosen from low index glass substrates, enamel layers based on low index glass frits and substrates made of low index polymer;
a central layer, preferably a dielectric layer composed of SiO₂ or TiO₂ or a metal layer such as a layer composed of Ag, NiCr, Ti, Cu or Au optionally surrounded by thin layers of other materials; and
an upper external layer composed of materials chosen from a substrate made of a low index polymer, a substrate made of low index glass, an enamel layer based on a low index glass frit and a layer of a preferably dielectric, low index transparent material.

Another subject of the invention is a process for manufacturing a device such as described above, comprising the following steps:

A) the carrier comprising the layered element is manufactured:
a transparent substrate is provided by way of a first external layer or lower external layer, one of the main surfaces of which is textured and the other main surface of which is smooth;
a central layer is deposited on the textured main surface of the lower external layer either, when the central layer is formed by a single layer that is a preferably dielectric, transparent layer with a refractive index different from that of the lower external layer or a metal layer, by depositing the central layer conformally on said textured main surface, or, when the central layer is formed by a stack of layers comprising at least one preferably dielectric, transparent layer with a refractive index different from that of the lower external layer or a metal layer, by depositing the layers of the central layer in succession conformally on said textured main surface;
the second external layer or upper external layer is formed on that textured main surface of the central layer which is opposite the lower external layer, the lower and upper external layers being composed of preferably dielectric, transparent materials having substantially the same refractive index; and
optionally at least one upper and/or lower additional layer is formed on the smooth external main surface or surfaces of the layered element; and

B) an electrode is deposited on said carrier.

According to one aspect of the invention, the second external layer is formed by depositing, on that textured main surface of the central layer which is opposite the first external layer, a layer of a material that has substantially the same refractive index as the first external layer and that is initially in a liquid or pasty viscous state suitable for shaping operations. The second external layer may thus be formed, for example, by a process comprising the deposition of a layer of photocrosslinkable and/or photopolymerizable material initially in the fluid form, followed by the irradiation of this layer, or by depositing a layer using a sol-gel process.

According to another aspect of the invention, the second external layer is formed by positioning, against that textured main surface of the central layer which is opposite the first external layer, a layer based on polymer material having substantially the same refractive index as the first external layer, and then by conforming this layer based on polymer material against the textured main surface of the central layer by compression and/or heating at least to the glass transition temperature of the polymer material. The layer based on polymer material is in this case an interlayer made of thermoformable or pressure-sensitive plastic.

According to another aspect of the invention, the second external layer is formed by injecting, into a mold, a molten polymer liable to form, after curing, a transparent polymer substrate. In this embodiment, the transparent substrate obtained after curing is preferably chosen from transparent substrates made of polyacrylic polymers and in particular of PMMA.

In the case of a transparent OLED, it may also be envisioned to use this light extraction solution both on the substrate and on the encapsulation, enabling light extraction from both sides of the OLED to be improved.

Features and advantages of the invention will become apparent from the following description of a plurality of embodiments of a layered element, this description being given merely by way of example and with reference to the appended drawings, in which:

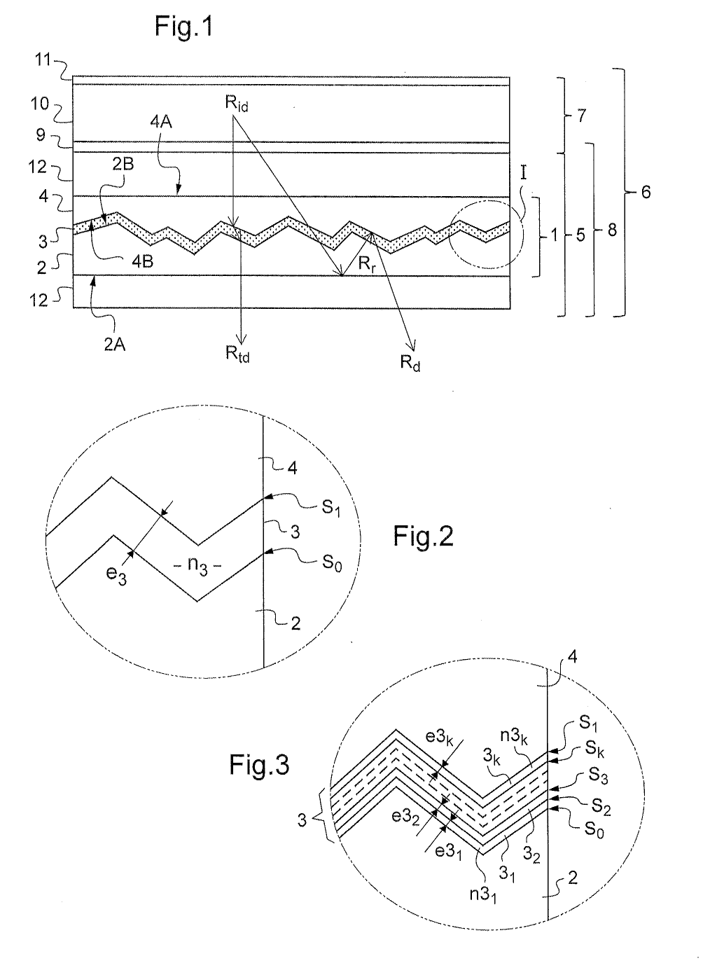

FIG. 1 is a schematic cross-sectional view of a diode device according to the invention;

FIG. 2 is a view on a larger scale of the detail I in FIG. 1 for a first variant of the layered element;

FIG. 3 is a view on a larger scale of the detail I in FIG. 1 for a second variant of the layered element;

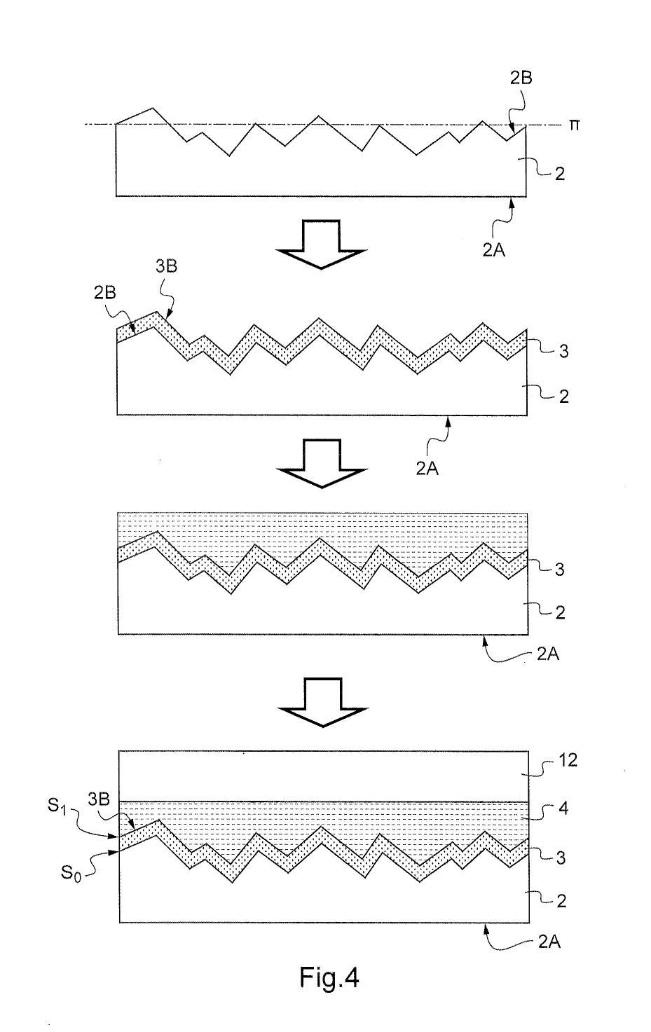

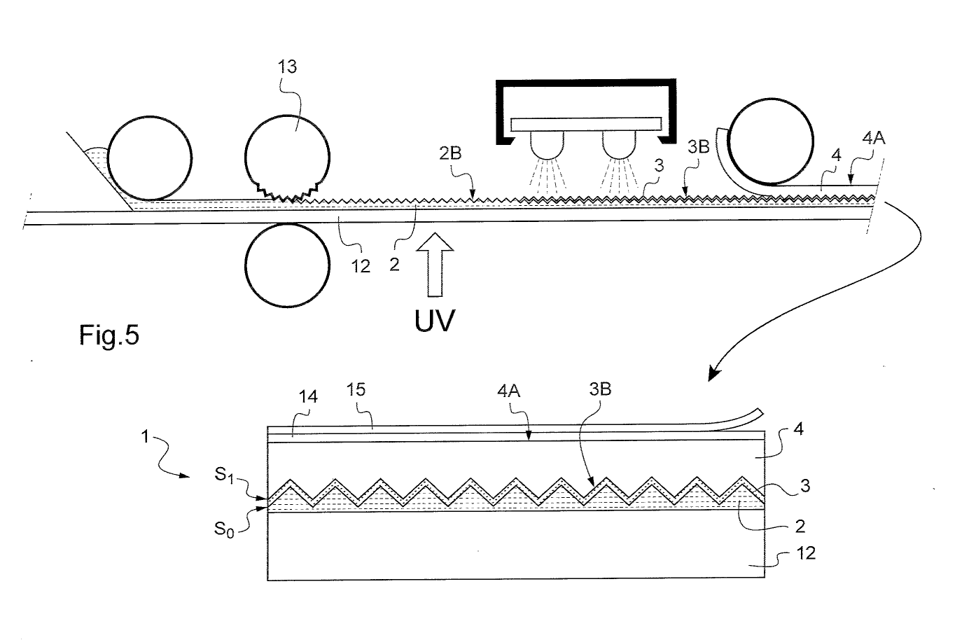

FIGS. 4 and 5 show diagrams showing the steps of a process for manufacturing a carrier used according to the invention; and

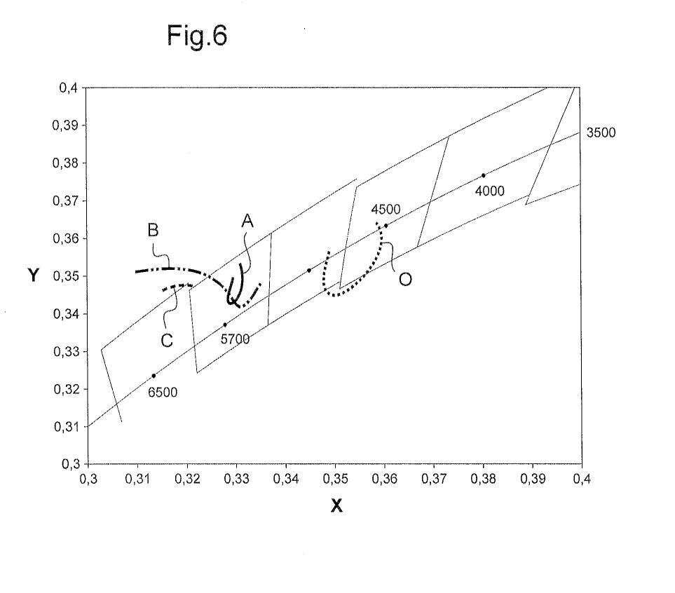

FIG. 6 is a graph showing color variations for the various OLED devices tested.

To ensure the drawings are clear, the relative thicknesses of the various layers in the figures are not rigorously to scale. Furthermore, possible variation in the thickness of the or each of the central layer as a function of the slope of the texture has not been shown in the figures, it being understood that this possible thickness variation does not have an impact on the parallelism of the textured contact surfaces. This is because, for each given slope of the texture, the textured contact surfaces are parallel to one another.

The organic light-emitting diode device 6 illustrated in FIG. 1 comprises a carrier 5 and an organic light-emitting diode 7. The carrier comprises a layered element 1 comprising two external layers 2 and 4 that are composed of transparent materials having substantially the same refractive index n2, n4. Each external layer 2 or 4 has a smooth main surface, 2A or 4A, respectively, directed toward the exterior of the layered element, and a textured main surface, 2B or 4B, respectively, directed toward the interior of the layered element.

The smooth external surfaces 2A and 4A of the layered element 1 ensure light is transmitted specularly at each surface 2A and 4A, i.e. light rays enter into the external layers and exit from the external layers without changing direction.

The textures of the internal surfaces 2B and 4B are complementary to one another. As may clearly be seen in FIG. 1, the textured surfaces 2B and 4B are positioned facing each other, in a configuration in which their textures are strictly parallel to each other. The layered element 1 also comprises a central layer 3 inserted between and making contact with the textured surfaces 2B and 4B.

The device also comprises an organic light-emitting diode 7 comprising two electrodes 9 and 11 and a layer or stack 10 of layers of organic material(s) one or more 10 of which are electroluminescent.

Lastly, the carrier also comprises upper and lower additional layers 12.

In the variant shown in FIG. 2, the central layer 3 is a monolayer and is composed of a transparent material that is either a metal, or transparent and of refractive index n3 different from that of the external layers 2 and 4. In the variant shown in FIG. 3, the central layer 3 is formed by a transparent stack of a plurality of layers 3₁, 3₂, . . . , 3ₖ, in which at least one of the layers 3₁ to 3ₖ is either a metal layer or a transparent layer of refractive index different from that of the external layers 2 and 4. Preferably, at least each of the two layers 3₁ and 3ₖ located at the ends of the stack is a metal layer or a transparent layer of refractive index n3₁ or n3ₖ different from that of the external layers 2 and 4.

In FIGS. 2 and 3, S₀ denotes the contact surface between the external layer 2 and the central layer 3, and S₁ denotes the contact surface between the central layer 3 and the external layer 4. Furthermore, in FIG. 3, S₂ to Sₖ successively denote the internal contact surfaces of the central layer 3, starting from the contact surface closest to the surface S₀.

In the variant of FIG. 2, because the central layer 3 is placed between and making contact with the textured surfaces 2B and 4B, which are parallel to one another, the contact surface S₀ between the external layer 2 and the central layer 3 is textured and parallel to the contact surface S₁ between the central layer 3 and the external layer 4. In other words, the central layer 3 is a textured layer exhibiting, over its entire extent, a uniform thickness e3, measured perpendicularly to the contact surfaces S₀ and S₁.

In the variant in FIG. 3, each contact surface S₂, . . . , Sₖ between two adjacent layers of the constituent stack of the central layer 3 is textured and strictly parallel to the contact surfaces S₀ and S₁ between the external layers 2, 4 and the central layer 3. Thus, all the contact surfaces S₀, S₁, . . . , Sₖ between adjacent layers of the element 1 that are either of different natures, transparent (and preferably nonmetal) or metal, or transparent and of different refractive indices, are textured and parallel to one another. In particular, each layer 3₁, 3₂, . . . , 3ₖ of the constituent stack of the central layer 3 has a uniform thickness e3₁, e3₂, . . . , e3ₖ, measured perpendicularly to the contact surfaces S₀, S₁, . . . , Sₖ.

The texture of each contact surface S₀, S₁ or S₀, S₁, . . . , Sₖ of the layered element 1 is formed by a plurality of features that are recessed or project with respect to a general plane it of the contact surface. Preferably, the mean height of the features of each textured contact surface S₀, S₁ or S₀, S₁, . . . , Sₖ is comprised between 1 micrometer and 1 millimeter.

According to one aspect of the invention, the thickness e3 or e3₁, e3₂, . . . , e3ₖ of the or each constituent layer of the central layer 3 is smaller than the mean height of the features of each textured contact surface S₀, S₁ or S₀, . . . , Sₖ of the layered element 1. This condition is important as it increases the probability that the entrance interface of a light ray into a layer of the central layer 3 and the exit interface of the light ray from this layer will be parallel, and thus increases the percentage of light rays transmitted specularly through the layered element 1. In order to make the various layers easier to see, this condition has not been strictly satisfied in the figures.

Preferably, the thickness e3 or e3₁, e3₂, . . . , e3ₖ of the or each constituent layer of the central layer 3 is less than ¼ of the mean height of the features of each textured contact surface of the layered element. In practice, when the central layer 3 is a thin layer or a stack of thin layers, the thickness e3 or e3₁, e3₂, . . . , e3ₖ of each layer of the central layer 3 is about, or less than, 1/10 of the mean height of the features of each textured contact surface of the layered element.

In the variant in FIG. 2, the contact surfaces S₀ and S₁ are parallel to one another, which implies, according to Snell's law, that n4. sin(θ)=n2. sin(θ′), where θ is the angle of incidence of the light ray on the central layer 3 starting from the external layer 4 and θ′ is the angle of refraction of the light ray in the external layer 2 starting from the central layer 3. In the variant in FIG. 3, as the contact surfaces S₀, S₁, . . . , Sₖ are all parallel to one another, the relationship n4. sin(θ)=n2. sin(θ′) resulting from the Snell's law is still applicable. Consequently, in both variants, as the refractive indices n2 and n4 of the two external layers are substantially equal to one another, the rays R_{td} transmitted by the layered element are transmitted with an angle of transmission θ′ equal to their angle of incidence θ on the layered element. The transmission of light rays by the layered element 1 is thus specular.

FIG. 1 also illustrates a light ray R_{id}, originating from the diode and incident on the carrier, that is trapped by total internal reflection at the air/substrate interface. The reflective ray Rᵣ may then be scattered by the rough surface of the central layer of the layered element. This scattered ray R_{d} then has an additional probability of being extracted from the device.

An example of a process for manufacturing the carrier 8 of the invention is described below with reference to FIG. 4. According to this process, the central layer 3 is deposited conformally on a textured surface 2B of a rigid or flexible transparent substrate forming the external layer 2 of the layered element 1. That main surface 2A of this substrate which is opposite the textured surface 2B is smooth. This substrate 2 may in particular be a textured glass substrate of Satinovo®, Albarino® or Masterglass® type. As a variant, the substrate 2 may be a substrate based on a rigid or flexible polymer material, polymethyl methacrylate or polycarbonate for example.

The conformal deposition of the central layer 3, whether it is a monolayer or formed by a stack of a plurality of layers, is in particular carried out, preferably, under vacuum, by magnetron cathode sputtering. This technique makes it possible to deposit, on the textured surface 2B of the substrate 2, either the single layer conformally or the different layers of the stack conformally in succession. They may in particular be thin transparent layers, preferably dielectric layers, in particular layers of Si₃N₄, SnO₂, ZnO, ZrO₂, SnZnOₓ, AlN, NbO, NbN, TiO₂, SiO₂, Al₂O₃, MgF₂ or AlF₃, or thin metal layers, in particular layers of silver, gold, titanium, niobium, silicon, aluminum, nickel-chromium alloy (NiCr) or alloys of these metals.

In the process in FIG. 4, the second external layer 4 of the layered element 1 may be formed by covering the central layer 3 with a transparent layer of a curable material of refractive index substantially equal to that of the substrate 2, this material initially being in a liquid or pasty viscous state suitable for shaping operations. This layer will, in the liquid or pasty viscous state, closely follow the texture of that surface 3B of the central layer 3 which is opposite the substrate 2. Thus, it is guaranteed that, once the layer 4 has been cured, the contact surface S₁ between the central layer 3 and the external layer 4 is indeed textured and parallel to the contact surface S₀ between the central layer 3 and the external layer 2.

The transparent layer of refractive index substantially equal to that of the substrate 2 may also take the form of a glass-frit-based enamel composition applied in a pasty state and cured in a firing step.

The transparent layer of refractive index substantially equal to that of the substrate 2 may also take the form of a layer of preferably dielectric, transparent material, for example deposited by magnetron deposition, that has its upper external surface polished in a polishing step.

Lastly, the transparent layer of refractive index substantially equal to that of the substrate 2 may also take the form of an interlayer made of plastic material. This layer undergoes a step of compression and/or heating at a temperature at least equal to the glass transition temperature of the polymer interlayer, for example in a press or an autoclave. In this step, the interlayer forming the upper layer of the textured layered element conforms to the texture and guarantees that the contact surface S₁ between the central layer 3 and the external layer 4 is indeed textured and parallel to the contact surface S₀ between the central layer 3 and the external layer 2.

Therefore, the second external layer 4 of the layered element 1 in FIG. 4 may especially be:
a layer of photocrosslinkable and/or photopolymerizable material, said layer being deposited, on the textured surface of the central layer 3, initially in a liquid form and then being cured by irradiation especially under UV radiation;
a sol-gel layer, in particular a silica glass deposited using a sol-gel process on the textured surface of the central layer 3;
an enamel layer deposited on the textured surface of the central layer 3;
a layer of preferably dielectric, transparent materials, said layer being deposited on the textured surface of the central layer 3; or
a transparent polymer lamination interlayer deposited on the textured surface of the central layer 3.

Lastly, one or more additional layers 12 may be formed above the layered element. In this case, the additional layer or layers are preferably a flat glass substrate, a plastic interlayer or a superposition of an interlayer and a flat glass substrate.

When the external layer of the layered element is obtained from a material initially in a liquid or pasty viscous state, a sol-gel for example, there may be certain irregularities on the smooth main external surface of this layer. In order to compensate for these irregularities, it may be advantageous to form an additional layer 12 on this sol-gel layer by positioning a PVB or EVA lamination interlayer against the smooth main external surface of the layered element. In this case, the additional layer 12 has substantially the same refractive index as the external layer of the layered element obtained from a material initially in a liquid or pasty viscous state.

The additional layer may also be a transparent substrate, for example a flat glass substrate. In this case, the additional layer is used as a counter-substrate. The layer that is initially deposited in a liquid or pasty viscous state then ensures a secure bond between the lower external layer provided with the central layer and the counter-substrate.

The use of a transparent substrate as upper additional layer is of particular use when the external layer or additional layer directly below said upper additional layer is formed by a polymer lamination interlayer.

In the case where the lower external layer 2 of the layered element is a glass substrate, the upper external layer 4 may be formed by a lamination interlayer, for example one made of PVB or EVA, that is positioned against that textured surface of the central layer 3 which is opposite the glass substrate. An additional layer 12 consisting of a flat glass substrate may be positioned above the interlayer 4.

The second external layer 4 may also be formed by a layer initially deposited in a liquid or pasty viscous state. A first additional layer 12 formed by a PVB or EVA lamination interlayer may be positioned against the upper external surface of the layered element and a second additional layer 12 composed of a flat glass substrate may be positioned above the interlayer.

In these configurations, the external layer and the additional layer or layers are associated with the glass substrate, which is coated beforehand with the central layer 3 using a conventional lamination process. In this process, the polymer lamination interlayer and the substrate are positioned, one after the other, on the textured main surface of the central layer 3 or on the upper external main surface of the layered element, and then the laminated structure thus formed is compressed and/or heated, at least to the glass transition temperature of the polymer lamination interlayer, for example in a press or an autoclave.

In this laminating process, when the interlayer forms the upper layer of the textured layered element it conforms to the texture and guarantees that the contact surface S₁ between the central layer 3 and the external layer 4 is indeed textured and parallel to the contact surface S₀ between the central layer 3 and the external layer 2.

In contrast, in this laminating process, if the interlayer forms the additional upper layer located directly above the layered element the upper layer of which is a sol-gel layer, it conforms both to the upper surface of the sol-gel layer and to the lower surface of the flat glass substrate.

In the process illustrated in FIG. 5, the carrier comprising the layered element 1 is a flexible film with a total thickness of about 200-300 μm. The carrier is formed by the superposition of:
a lower additional layer 12 formed by a flexible polymeric film;
an external layer 2 made of material that is photocrosslinkable and/or photopolymerizable under the action of UV radiation, said layer being applied against one of the smooth main surfaces of the flexible film;
a central layer 3; and
a second film of PET having a thickness of 100 μm, forming the second external layer 4 of the layered element 1.

The flexible film forming the lower additional layer may be a film of polyethylene terephthalate (PET) having a thickness of 100 μm, and the external layer 2 may be a layer of resin curable under UV radiation of KZ6661 type, sold by JSR Corporation, having a thickness of approximately 10 μm. The flexible film and the layer 2 both have substantially the same refractive index, of about 1.65 at 550 nm. In the cured state, the layer of resin exhibits a good adhesion with PET.

The layer of resin 2 is applied to the flexible film with a viscosity which makes it possible to texture its surface 2B opposite the film 12. As illustrated in FIG. 5, the surface 2B may be textured using a roll 13 having, at its surface, a texture complementary to that to be formed on the layer 2. Once the texture has been formed, the superposed flexible film and layer of resin 2 are irradiated with UV radiation, as shown by the arrow in FIG. 5, which makes it possible to solidify the layer of resin 2 with its texture and to assemble together the flexible film and the layer of resin 2.

The central layer 3 with a refractive index different from that of the external layer 2 is subsequently deposited conformally on the textured surface 2B by magnetron cathode sputtering. This central layer may be a monolayer or be formed by a stack of layers, as described above. It may, for example, be a layer of TiO₂ having a thickness comprised between 55 and 65 nm, i.e. of about 60 nm, and a refractive index of 2.45 at 550 nm.

A second film of PET having a thickness of 100 μm is then deposited on the central layer 3 so as to form the second external layer 4 of the layered element 1. This second external layer 4 is conformed to that textured surface 3B of the central layer 3 which is opposite the external layer 2 by compression and/or heating to the glass transition temperature of the PET.

A layer of adhesive 14 covered with a protective strip (liner) 15 intended to be removed for the adhesive bonding may be added to the external surface 4A of the layer 4 of the layered element 1. The layered element 1 thus takes the form of a flexible film ready to be added by adhesive bonding to a surface, such as a surface of an electrode or of an organic light-emitting diode.

Particularly advantageously, as suggested in FIG. 5, the different steps of the process may be carried out continuously on one and the same manufacturing line.

It will be noted that, in each of the processes illustrated in these figures, an electrode may be placed onto the smooth surfaces 2A or 4A of the external layers, or optionally on an upper or lower additional layer, before or after the layered element has been assembled, depending on the nature of said layers.

The invention is not limited to the examples described and shown. In particular, when the layered element is a flexible film, as in the example of FIG. 5, each external layer formed based on a polymer film, for example based on a film of PET, may be greater than 10 μm in thickness and in particular about 10 μm to 1 mm in thickness.

In addition, the first external layer 2 in the example of FIG. 5 may be textured, without resorting to a layer of curable resin deposited on the polymer film, by directly hot embossing a polymer film, in particular by rolling using a textured roll or by pressing using a punch.

In order to improve the cohesion of the layered element taking the form of a flexible film illustrated in FIG. 5, a polymer lamination interlayer may be inserted between the central layer 3 and the second polymer film. This interlayer then forms the upper external layer of the layered element and the second polymer film forms an upper additional layer. In this case, the lamination interlayer has substantially the same refractive index as the polymer films flanking it. In this case, it is a question of a conventional laminating process in which the laminated structure is compressed and/or heated at least to the glass transition temperature of the polymer lamination interlayer.

Analogous architectures may also be envisioned for plastic substrates in place of glass substrates.

Generally, applications of an organic light-emitting diode device according to the invention include display screens or illuminating devices.

### EXAMPLES

### I. Preparation of Carriers and OLED Devices

| Example | Carrier 1 | Carrier 2 | Carrier 3 | Carrier 4 | Carrier 5 |
|---|---|---|---|---|---|
| Lower | — | — | Flat glass | — | Glass |
| additional | | | | | |
| layer | | | | | |
| Lower | Satinovo ® | Schott ® | Enamel | Schott ® | Enamel |
| external | | SF66 | layer | SF66 | layer |
| layer | | | | | |
| Central | TiO₂ | TiO₂ | TiO₂ | Ag | Ag |
| layer | | | | | |
| Upper | NOA75 ® | SnZnO | SnZnO | SnZnO | SnZnO |
| external | | | | | |
| layer | | | | | |
| Upper | Planilux ® | — | — | — | — |
| additional | | | | | |
| layer | | | | | |

The transparent SATINOVO® (from Saint-Gobain) rough glass substrate used had a thickness of 0.7 mm and had on one of its main surfaces a texture obtained by acid attack. The mean height of the features of the texture of this lower external layer, which corresponds to the roughness Ra of the textured surface of the Satinovo® glass, was comprised between 1 and 3 μm. Its refractive index was 1.52 and its PV (peak to valley) roughness, corresponding to the maximum valley-to-peak deviation, was comprised between 12 and 17 μm.

The additional layers comprised a 0.7 mm-thick flat Planilux® glass sheet sold by Saint-Gobain.

The glass referenced SF66 sold by Schott has a refractive index of 1.92. When it was used as a lower external layer, it was textured by sandblasting.

The layer of resin NOA75® from Norland Optics had a refractive index of 1.52 and a thickness of 100 μm. This resin was deposited in the liquid state on that textured surface of the central layer which was opposite the lower external layer in such a way that it closely followed the texture of the surface, and it was then cured under the action of UV radiation.

The other central layers were deposited by magnetron cathode sputtering on the textured surface of the lower external layer. The TiO₂ layer was deposited with a thickness of 60 nm under the following deposition conditions: TiO₂ target, deposition pressure of 2×10⁻³ mbar, gas composed of a mixture of argon and oxygen. The silver layer was deposited with a thickness of 20 nm.

The upper external layer composed of a layer of SnZnO was deposited by magnetron sputtering. Since magnetron deposition is conformal, it was followed by a polishing step in order to obtain a sufficiently smooth exterior surface.

The high refractive index enamel layer (refractive index of 1.9) was obtained by depositing, onto a soda-lime glass substrate, a high index glass enamel having the following composition, the values being percentages by weight:

| | |
|---|---|
| SiO₂: 3.8%, | B₂O₃: 15.6%, |
| ZrO₂: 4.4%, | ZnO: 17.4%, |
| K₂O: 0.8%, | Na₂O: 2.5% |
| Al₂O₃: 0.4%, | Bi₂O₃: 54.6%. |

To prepare the carrier 1, the photopolymerizable material was applied to a sheet of Satinovo® glass covered with a layer of TiO₂. Next, a flat glass sheet was superposed. The assembly was irradiated with UV so as to polymerize the photopolymerizable material, which then also securely bonded all of the constituent elements of the carrier.

For carriers 2 to 5, the upper external layer was a transparent layer or a layer covered with SnZnO deposited by magnetron sputtering and having an index close to that of the lower external layer. This layer could also have been a layer having a suitable refractive index chosen from Si₃N₄, ZnO or MoO₃.

This layer was then polished in order to smooth its external main surface.

For carriers 4 and 5, the central layer comprised a metal layer made of silver. This layer could also have been made of gold or copper. This metal layer may then form one of the electrodes of the OLED device. The assembly composed of the central layer and the upper external layers preferably forms the lower electrode of the OLED.

The light-emitting diodes used were the Lumiblade® white-light OLEDs as sold by Phillips in 2012.

These diodes were adhesively bonded to the carriers 1 to 3 with the dimethyl phthalate sold by Merck and thus the diode devices 1 to 3 according to the invention were formed.

### II. Comparative OLED Devices

The optical properties of the OLED device of the invention comprising carrier 1, device (A) below, were compared:
to a bare OLED with no carrier (O);
to a device comprising an OLED diode fastened to the smooth side of a 0.7 mm-thick Satinovo® glass sheet, corresponding to a rough substrate, device (B) below; and
to a device comprising an OLED diode fastened to a 0.7 mm-thick flat glass sheet provided with a scattering layer that was a bismuth frit with 30% alumina particles, device (C) below.

Comparative OLED
device

| | O | B | C |
|---|---|---|---|
| OLED | Lumiblade | Lumiblade | Lumiblade |
| Carrier | No carrier | Rough glass | Flat glass |
| | | | Scattering layer |

These three comparative examples used an OLED that was identical to that used in the device of the invention, i.e. a Lumiblade® white OLED as sold by Phillips in 2012.

### III. Evaluation of Optical Properties

The optical properties of the various examples given in table 1 below comprise:
light transmission T_{L} in the visible in %, measured according to standard ISO 9050:2003 (illuminant D65; 2° observer);
haze in transmission (Haze T) in %, measured by a hazemeter according to standard ASTM D 1003 for light incident on the layered element from the lower-external-layer side; and
gain in extraction measured using an integrating sphere and as given by the following formula:

$$G ( \% ) = 100 \cdot ( \frac{{Flux}_{solution} - {Flux}_{Reference}}{{Flux}_{Reference}} ) .$$

The table also gives the color variation Vc as a function of angle of observation, i.e. the length of the path (of various shapes such as a straight line or a circular arc), in the CIE (1931) XYZ color space, between the spectrum emitted at 0° and the spectrum emitted at 75°, in steps of 5°. The color coordinates for each spectrum of angle θi are expressed by the pair of coordinates (x(θi);y(θi)) in the CIE (1931) XYZ color space. The length of the path Vc1 for the device according to the invention may therefore be calculated using the following known formula:

$${V}_{C 1} = {\sum }_{{θ}_{i} = 0}^{{θ}_{i} = {75}^{°}} \sqrt{{( x ( {θ}_{i} ) - x ( {θ}_{i + 1} ) )}^{2} + {( y ( {θ}_{i} ) - y ( {θ}_{i + 1} ) )}^{2}}$$

The length of the path must be as short as possible in order to minimize the angular dependence of the color of the OLED. Lastly, the color variation Vc makes it possible to get an idea of how much the color will vary with angle once the OLED has been produced.

| | Device | | | |
|---|---|---|---|---|
| | O | A | B | C |
| Substrate TL | — | 79% | 87% | 59% |
| Substrate haze | — | 3-4% | 90% | 100% |
| Gain | — | 22-24% | 43% | 40% |
| Vc | 36 × 10⁻³ | 18 × 10⁻³ | 33 × 10⁻³ | 7 × 10⁻³ |

The device of the invention allows the best compromise to be obtained between a good light transmission, a minimum haze, a gain in extraction and a decrease in color variations with angle. The color variations obtained are shown in FIG. 6. The device of the invention allows both a gain in extraction to be obtained and color variations with angle to be decreased while maintaining a high transparency (haze lower than 4%).

1. An organic light-emitting diode device comprising at least one organic light-emitting diode and a carrier comprising a transparent layered element having two smooth main external surfaces, the transparent layered element comprising:
two external layers, which each form one of the two smooth external main surfaces of the transparent layered element and which are composed of transparent materials having substantially a same refractive index, and
a central layer inserted between the two external layers, the central layer being formed either (a) by a single layer which is a transparent layer with a refractive index different from that of the two external layers, or a metal layer, or (b) by a stack of layers which comprises at least one transparent layer with a refractive index different from that of the two external layers, or a metal layer,
wherein each contact surface between two adjacent layers of the transparent layered element, one of which being transparent with a refractive index and the other metal or which are both transparent layers with different refractive indices, is textured and parallel to other textured contact surfaces between two adjacent layers, one of which being transparent with a refractive index and the other metal, or which are both transparent layers with different refractive indices.

2. The organic light-emitting diode device as claimed in claim 1, wherein the carrier further comprises at least one additional layer positioned above or below the transparent layered element, said additional layer being chosen from:
transparent substrates chosen from polymers, glasses or ceramics comprising two smooth main surfaces,
curable materials initially in a liquid or pasty viscous state suitable for shaping operations,
interlayers made of thermoformable or pressure-sensitive plastic.

3. The organic light-emitting diode device as claimed in claim 1, wherein at least one of the two external layers of the transparent layered element is chosen from:
transparent substrates one of the main surfaces of which is textured and the other smooth,
a layer of transparent material chosen from oxides, nitrides or halides of one or more transition metals, nonmetals or alkaline-earth metals,
a layer based on curable materials initially in a liquid or pasty viscous state suitable for shaping operations comprising:
photocrosslinkable and/or photopolymerizable materials,
layers deposited by a sol-gel process,
enamel layers,
interlayers made of thermoformable or pressure-sensitive plastic.

4. The organic light-emitting diode device as claimed in claim 1, wherein the (a) single layer or (b) the stack of layers of the central layer comprises a layer chosen from:
at least one adhesive layer made of transparent polymer,
at least one thin layer composed of a transparent material chosen from oxides, nitrides or halides of one or more transition metals, nonmetals or alkaline-earth metals,
at least one thin metal layer of silver, gold, copper, titanium, niobium, silicon, aluminum, nickel-chromium alloy, stainless steel or their alloys.

5. The organic light-emitting diode device as claimed in claim 1, wherein the carrier comprises:
optionally at least one lower additional layer chosen from transparent substrates, the two main surfaces of which are smooth, the optionally at least one lower additional layer chosen from polymers and glasses and interlayers made of thermoformable or pressure-sensitive plastic, and
optionally at least one upper additional layer chosen from transparent substrates, the two main surfaces of which are smooth, the optionally at least one upper additional layer chosen from polymers and glasses and interlayers made of thermoformable or pressure-sensitive plastic,
wherein a first of the two external layers that is closer to the optionally at least one lower additional layer is a lower external layer chosen from transparent substrates chosen from polymers and glasses and curable materials initially in a liquid or pasty viscous state suitable for shaping operations, and
wherein a second of the two external layers that is closer to the optionally at least one upper additional layer is an upper external layer chosen from transparent substrates chosen from polymers and glasses, curable materials initially in a liquid or pasty viscous state suitable for shaping operations and interlayers made of thermoformable or pressure-sensitive plastic.

6. The organic light-emitting diode device as claimed in claim 1, wherein the carrier comprises:
an upper additional layer chosen from transparent substrates made of flat glass,
wherein a first of the two external layers that is farther away from the upper additional layer is a lower external layer chosen from transparent substrates made of rough glass,
wherein the central layer comprises a thin TiO₂ layer,
wherein a second of the two external layers that is closer to the upper additional layer is an upper external layer chosen from photocrosslinkable and/or photopolymerizable resins.

7. The organic light-emitting diode device as claimed in claim 1, wherein the two external layers of the transparent layered element are composed of transparent materials having a high refractive index comprised between 1.7 and 2.4.

8. The organic light-emitting diode device as claimed in claim 7, wherein the carrier comprises
wherein a first of the two external layers is a lower external layer chosen from transparent substrates made of glass or high index polymer; or
wherein a first of the two external layers is a lower additional layer chosen from transparent substrates made of glass coated with an external layer composed of a high refractive index enamel layer
wherein a second of the two external layers is an upper external layer chosen from a transparent substrate made of polymer or of high index glass, a high index enamel layer, a layer of high index transparent material.

9. The organic light-emitting diode device as claimed in claim 1, wherein the central layer of the layered element and/or the external layer of the layered element closer to the organic light-emitting diode form a lower electrode of the organic light-emitting diode.

10. The organic light-emitting diode device as claimed in claim 1, wherein
the central layer is a metal layer, and
the external layer of the layered element closer to the organic light-emitting diode is composed of transparent materials having a resistivity lower than 1 ohm.cm.

11. The organic light-emitting diode device as claimed in claim 1, wherein a light transmission of the organic light-emitting diode device is at least 50% and the haze in transmission is lower than 20%.

12. The organic light-emitting diode device as claimed in claim 1, wherein the organic light-emitting diode comprises:
a transparent first electrode formed from one or more layers,
above the transparent first electrode, an organic light-emitting system, and
a transparent second electrode formed from one or more layers, said transparent second electrode being deposited on the organic light-emitting system, opposite the transparent first electrode.

13. The organic light-emitting diode device as claimed in claim 1, wherein the organic light-emitting diode comprises:
a transparent first electrode formed from one or more layers,
above the transparent first electrode, an organic light-emitting system, and
a reflective second electrode formed from one or more layers, said reflective second electrode being deposited on the organic light-emitting system, opposite the transparent first electrode.

14. A carrier coated with an electrode, said carrier comprising at least one transparent layered element having two smooth external main surfaces, said transparent layered element comprising:
two external layers, which each form one of the two smooth external main surfaces of the transparent layered element and which are composed of transparent materials having substantially a same refractive index, and
a central layer inserted between the two external layers, the central layer being formed either (a) by a single layer which is a transparent layer with a refractive index different from that of the external layers, or a metal layer, or (b) by a stack of layers which comprises at least one transparent layer with a refractive index different from that of the external layers, or a metal layer,
wherein each contact surface between two adjacent layers of the transparent layered element, one of which being transparent with a refractive index and the other metal or which are both transparent layers with different refractive indices, is textured and parallel to other textured contact surfaces between two adjacent layers, one of which being transparent with a refractive index and the other metal or which are both transparent layers with different refractive indices.

15. A process for manufacturing an organic light-emitting diode device, the process comprising:
manufacturing a carrier comprising a layered element, the manufacturing including
providing a transparent substrate forming a lower external layer, the lower external layer having two main surfaces, one of the main surfaces of the lower external layer being textured and the other main surface of the lower external layer being smooth;
depositing a central layer on the textured main surface of the lower external layer either (a), when the central layer is formed by a single layer that is a transparent layer with a refractive index different from that of the lower external layer or a metal layer, by depositing the central layer conformally on said textured main surface, or (b), when the central layer is formed by a stack of layers comprising at least one transparent layer with a refractive index different from that of the lower external layer or a metal layer, by depositing the stack of layers of the central layer in succession conformally on said textured main surface;
forming an upper external layer on that textured main surface of the central layer which is opposite the lower external layer, the lower and upper external layers being composed of transparent materials having substantially the same refractive index; and
optionally forming at least one upper and/or lower additional layer on the smooth external main surface or surfaces of the layered element; and
depositing an electrodes on said carrier.

16. The organic light-emitting diode device as claimed in claim 1, wherein the transparent materials of the two external layers are dielectric materials.

17. The organic light-emitting diode device as claimed in claim 1, wherein the single layer is a dielectric layer.

18. The organic light-emitting diode device as claimed in claim 1, wherein the at least one transparent layer is a dielectric layer.

19. The organic light-emitting diode device as claimed in claim 3, wherein the transparent substrates one of the main surfaces of which is textured and the other smooth are chosen from polymers, glasses and ceramics.

20. The organic light-emitting diode device as claimed in claim 3, wherein the interlayers made of thermoformable or pressure-sensitive plastic are based on polymers chosen from polyvinyl butyrals (PVB), polyvinyl chlorides (PVC), polyurethanes (PU), polyethylene terephthalates or ethylene/vinyl acetates (EVA).

21. The carrier as claimed in claim 14, wherein the transparent materials of the two external layers are dielectric materials.

22. The carrier as claimed in claim 14, wherein the single layer is a dielectric layer.

23. The carrier as claimed in claim 14, wherein the at least one transparent layer is a dielectric layer.
